(19) United States
(12) Patent Application Publication
(10) Pub. No.: US 2025/0301628 A1
(43) Pub. Date: Sep. 25, 2025

(54) GATE ALL AROUND FIELD EFFECT TRANSISTOR INCLUDING VERTICAL PILLAR AND FABRICATION METHOD THEREFOR

(71) Applicants: ELECTRONICS AND TELECOMMUNICATIONS RESEARCH INSTITUTE, Daejeon (KR); Korea Advanced Institute Of Science And Technology, Daejeon (KR); KOREA INSTITUTE OF SCIENCE AND TECHNOLOGY, Seoul (KR)

(72) Inventors: Sung Haeng CHO, Daejeon (KR); Seong Keun KIM, Seoul (KR); Byung Jin CHO, Daejeon (KR)

(73) Assignees: ELECTRONICS AND TELECOMMUNICATIONS RESEARCH INSTITUTE, Daejeon (KR); Korea Advanced Institute Of Science And Technology, Daejeon (KR); KOREA INSTITUTE OF SCIENCE AND TECHNOLOGY, Seoul (KR)

(21) Appl. No.: 19/079,998

(22) Filed: Mar. 14, 2025

(30) Foreign Application Priority Data
Mar. 20, 2024 (KR) 10-2024-0038713
Mar. 10, 2025 (KR) 10-2025-0030495

(51) Int. Cl. H10B 12/00

(52) U.S. Cl. CPC H10B 12/315; H10B 12/033; H10B 12/05; H10B 12/482; H10B 12/488

(57) ABSTRACT

A semiconductor memory device using gate all around transistor may comprise: a plurality of bit lines extending in a first direction; a plurality of word lines positioned vertically higher than the plurality of bit lines and extending in a second direction intersecting the first direction; a plurality of storage node capacitors positioned vertically higher than the plurality of word lines and stacked on a plurality of intersection regions where the plurality of bit lines and the plurality of word lines intersect; and a plurality of oxide semiconductor channel pillars arranged to connect the plurality of bit lines and the plurality of storage node capacitors while penetrating into the plurality of word lines on the plurality of intersection regions, wherein the plurality of word lines surrounds the plurality of oxide semiconductor channel pillars as gate terminals on the plurality of intersection regions.

### CROSS-REFERENCE TO RELATED APPLICATIONS

This application claims priority to Korean Patent Applications No. 10-2024-0038713,filed on Mar. 20, 2024, and No. 10-2025-0030495, filed on Mar. 10, 2025, with the Korean Intellectual Property Office (KIPO), the entire contents of which are hereby incorporated by reference.

### BACKGROUND

### 1. Technical Field

The disclosure belongs to a technical field of fabricating a semiconductor device, and specifically relates to a transistor for implementing a semiconductor memory device and a fabrication method thereof.

### 2. Related Art

The statements in this section merely provide background information related to the present embodiments and may not constitute the prior art.

A dynamic random-access memory (DRAM), i.e., a main memory of a computer is mostly configured with a cell that includes one transistor and one capacitor, which is called a 1T-1C structure. The DRAM cell expresses 0 or 1 based on the difference or presence of charge stored in the capacitor.

A fabrication process technology for the DRAM has been developed in consideration of the integration of a memory array, data writing/reading speed, data storage time, and fabrication costs, etc. In particular, the development of cell structures and process technologies capable of improving the integration while maintaining a constant data retention time (64 ms in the JEDEC standards) has been the main goal and standard for the development of DRAM process technology.

To improve the integration, both the cell array transistor (CAT) and the capacitor, which constitute a unit cell, are required to be decreased in size.

In a general Si semiconductor, when the CAT has a channel length of 1 μm or less, a problem of shortening data storage time arises due to increase in junction leakage currents or short channel effects including drain induced barrier lowering (DIBL), gate induced drain leakage (GIDL), etc.

To solve these problems, the structure of the CAT has been developed in the forms of a recess cell array transistor (RCAT), a spherical recess cell array transistor (S-RCAT), and a saddle fin, etc. from a planar structure.

The structure of the capacitor has also been developed in the direction of using a high dielectric insulating film to maximize the capacitance of the capacitor in a reduced area, or applying various three-dimensional structures to increase the surface area.

To increase the cell integration per two-dimensional area, it has recently been required to develop a so-called vertical cell array transistor (VCAT) in which a storage node contact (SNC), i.e. a capacitor, is located on a region where a line BL and a word line WL intersect perpendicularly.

### SUMMARY

The disclosure has been conceived to solve the problems of the related art, and an aspect of the disclosure is to propose a vertical cell array transistor (VCAT) structure based on a Gate-All-Around (GAA) field effect transistor by using an oxide semiconductor having low leakage current characteristics to form a cell array transistor (CAT) and combine with a vertical pillar structure as a method of achieving a unit cell area of 4F² less for a memory array in a DRAM device.

An aspect of the disclosure is to propose an effective VCAT structure using an oxide semiconductor as a main material for a CAT, in which the oxide semiconductor has a very low leakage current characteristic of 10⁻²⁰ A/μm or less due to a high bandgap of about 3 eV, very low hole concentration, and low hole mobility characteristics.

The disclosure also aims to propose an effective process for manufacturing a memory device having a VCAT structure based on the oxide semiconductor.

According to a first exemplary embodiment of the present disclosure, a semiconductor memory device using gate all around transistor may comprise: a plurality of bit lines extending in a first direction; a plurality of word lines positioned vertically higher than the plurality of bit lines and extending in a second direction intersecting the first direction; a plurality of storage node capacitors positioned vertically higher than the plurality of word lines and stacked on a plurality of intersection regions where the plurality of bit lines and the plurality of word lines intersect; and a plurality of oxide semiconductor channel pillars arranged to connect the plurality of bit lines and the plurality of storage node capacitors while penetrating into the plurality of word lines on the plurality of intersection regions, wherein the plurality of word lines surrounds the plurality of oxide semiconductor channel pillars as gate terminals on the plurality of intersection regions.

The semiconductor memory device may further comprise a gate dielectric disposed between lateral sides of the plurality of oxide semiconductor channel pillars and the plurality of word lines, and surrounding the plurality of oxide semiconductor channel pillars.

The plurality of storage node capacitors may be extended to cover the plurality of oxide semiconductor channel pillars and gate terminals surrounding the plurality of oxide semiconductor channel pillars on the plurality of intersection regions, and a portion of the plurality of storage node capacitors may be formed to be in direct contact with a lateral surface of a portion of the plurality of oxide semiconductor channel pillars while surrounding the lateral surface of the portion of the plurality of oxide semiconductor channel pillars.

The plurality of storage node capacitors may be extended to cover the plurality of oxide semiconductor channel pillars and a gate dielectric surrounding the plurality of oxide semiconductor channel pillars on the plurality of intersection regions, and a lower portion of the plurality of storage node capacitors may be formed to be in direct contact with an upper surface of the plurality of oxide semiconductor channel pillars.

The plurality of oxide semiconductor channel pillar may be formed of an oxide semiconductor compound that contains two or more elements from a group consisting of In, Ga, Zn, Sn, and O and has a band gap energy of 1.5 eV or more.

The plurality of oxide semiconductor channel pillar may be formed of an oxide semiconductor compound that contains at least one element of Al, W, Hf, and/or Ta as impurities.

The gate dielectric may comprise a dielectric film that contains at least one of Al₂O₃, SiO₂, HfOₓ, and/or ZrOₓ.

The plurality of word lines and the plurality of bit lines may be insulated by a first dielectric, and the plurality of storage node capacitors and the plurality of word lines may be insulated by a second dielectric.

The plurality of oxide semiconductor channel pillars and the gate terminals surrounding the plurality of oxide semiconductor channel pillars may operate as access transistors of a dynamic random-access memory (DRAM) having a 1T-1C (1 Transistor 1 Capacitor) structure, and the plurality of storage node capacitors may operate as storage nodes of the DRAM having the 1T-1C structure.

The plurality of oxide semiconductor channel pillars and the gate terminals surrounding the plurality of oxide semiconductor channel pillars may operate respectively as a write transistor of the DRAM having a 2T-OC (2 Transistor 0 Capacitor) structure, the plurality of storage node capacitors may operate as a storage node between the write transistor and a read transistor of the DRAM having the 2T-OC structure, and the plurality of bit lines may operate as write bit line (WBL) of the DRAM having the 2T-OC structure.

According to a second exemplary embodiment of the present disclosure, a fabrication method of a semiconductor device may comprise: providing a first semiconductor device structure comprising a plurality of first storage node capacitors (electrodes) stacked on a plurality of intersection regions where a plurality of bit lines extending in a first direction and a plurality of word lines extending in a second direction intersecting the first direction intersect;

forming a vertical channel hole penetrating the plurality of word lines in the plurality of intersection regions by etching the plurality of first storage node capacitors and the plurality of word lines in the plurality of intersection regions of the first semiconductor device structure; depositing a gate dielectric on a lateral side of the vertical channel hole; forming vertical oxide semiconductor channel pillars by depositing an oxide semiconductor material inside the vertical channel hole and the gate dielectric; and forming a cell array transistor (CAT) by additionally depositing and patterning a second storage node capacitor (electrode) on the plurality of intersection regions.

The plurality of first storage node capacitors (electrodes) remaining after forming the vertical channel hole may be formed to be in direct contact with a lateral surface of a portion of the vertical oxide semiconductor channel pillars while surrounding the lateral surface of the portion of the vertical oxide semiconductor channel pillars, and the second storage node capacitors may be extended to cover the vertical oxide semiconductor channel pillars and a portion of the plurality of word lines surrounding the vertical oxide semiconductor channel pillars on the plurality of intersection regions.

The forming the vertical oxide semiconductor channel pillars may comprise: depositing an oxide semiconductor material comprising an oxide semiconductor compound that contains two or more elements from a group consisting of In, Ga, Zn, Sn, and O and has a band gap energy of 1.5 eV or more.

The oxide semiconductor material may comprise an oxide semiconductor compound that contains at least one element among Al, W, Hf, and/or Ta as impurities.

The depositing the gate dielectric may comprise depositing the gate dielectric comprising a dielectric film that contains at least one of Al₂O₃, SiO₂, HfOₓ, and/or ZrOₓ.

According to a third exemplary embodiment of the present disclosure, a fabrication method of a semiconductor device may comprise: providing a second semiconductor device structure comprising a plurality of bit lines extending in a first direction and a plurality of word lines extending in a second direction intersecting the first direction; forming a vertical channel hole penetrating the plurality of word lines in a plurality of intersection regions by etching the plurality of word lines in the plurality of intersection regions of the second semiconductor device structure; depositing a gate dielectric on a lateral side of the vertical channel hole;

forming vertical oxide semiconductor channel pillars by depositing an oxide semiconductor material inside the vertical channel hole and the gate dielectric; and forming a cell array transistor (CAT) by depositing a plurality of storage node capacitors on the plurality of intersection regions.

The plurality of storage node capacitors may extend to cover the vertical oxide semiconductor channel pillars and the gate dielectric surrounding the vertical oxide semiconductor channel pillars on the plurality of intersection regions, and a lower portion of the plurality of storage node capacitors may be formed to be in direct contact with an upper surface of the vertical oxide semiconductor channel pillars.

The forming the vertical oxide semiconductor channel pillars may comprise: depositing the oxide semiconductor material that contains two or more elements from a group consisting of In, Ga, Zn, Sn, and O and has a band gap energy of 1.5 eV or more.

The oxide semiconductor material may comprise an oxide semiconductor compound that contains at least one element among Al, W, Hf, and/or Ta as impurities.

The depositing the gate dielectric may comprise: depositing the gate dielectric comprising a dielectric film that contains at least one of Al₂O₃, SiO₂, HfOₓ, and/or ZrOₓ.

According to an embodiments of the disclosure, a DRAM memory cell having an area of 4F2 (where, F refers to Minimum Feature Size) may be achieved using the oxide semiconductor transistor process technology.

According to an embodiment of the disclosure, the oxide semiconductor channel is used instead of the conventional Si-based channel, thereby applying a low-temperature process of less than 400 degrees to the memory semiconductor fabrication process.

According to an embodiment of the disclosure, a 3D stacking process is possible using a monolithic fabrication process without relying on 2.5D or 3D packaging technologies such as a through silicon via (TSV) or an Si interposer for the conventional 3D semiconductor packaging.

### BRIEF DESCRIPTION OF DRAWINGS

FIG. 1 is a cross-sectional view conceptually showing a semiconductor device 110 that has undergone some steps of a semiconductor fabrication process according to an embodiment of the disclosure.

FIG. 2 is a plan view showing the semiconductor device 110 of FIG. 1.

FIG. 3 is a cross-sectional diagram conceptually illustrating the semiconductor device 120 formed by applying some additional steps to the semiconductor device 110 of FIGS. 1 and 2.

FIG. 4 is a plan view showing the semiconductor device 120 of FIG. 3.

FIG. 5 is a cross-sectional view conceptually showing a semiconductor device 130 formed by applying some additional steps to the semiconductor device 120 of FIGS. 3 and 4. FIG. 6 is a cross-sectional view conceptually showing a semiconductor device 140 formed by applying some additional steps to the semiconductor device 130 of FIG. 5. FIG. 7 is a plan view showing the semiconductor device 140 of FIG. 6.

FIG. 8 is a cross-sectional view conceptually showing a semiconductor device 150 formed by applying some additional steps to the semiconductor device 140 of FIGS. 6 and 7.

FIG. 9 is a cross-sectional view conceptually showing a semiconductor device 160 formed by applying some additional steps to the semiconductor device 150 of FIG. 8.

FIG. 10 is a cross-sectional view conceptually showing a semiconductor device 170 formed by applying some additional steps to the semiconductor device 160 of FIG. 9. FIG. 11 is a plan view showing the semiconductor device 170 of FIG. 10.

FIG. 12 is a cross-sectional view conceptually showing a semiconductor device 180 formed by applying some additional steps to the semiconductor device 170 of FIGS. 10 and 11.

FIG. 13 is a plan view showing the semiconductor device 180 of FIG. 12.

FIG. 14 is a cross-section view conceptually showing a semiconductor device 310 that has undergone some steps of a semiconductor fabrication process according to another embodiment of the disclosure.

FIG. 15 is a plan view showing the semiconductor device 310 of FIG. 14.

FIG. 16 is a cross-section view conceptually showing a semiconductor device 320 formed by applying some additional steps to the semiconductor device 310 of FIGS. 14 and 15. FIG. 17 is a cross-section view conceptually showing a semiconductor device 330 formed by applying some additional steps to the semiconductor device 320 of FIG. 16.

FIG. 18 is a plan view showing the semiconductor device 330 of FIG. 17.

FIG. 19 is a cross-section view conceptually showing a semiconductor device 340 formed by applying some additional steps to the semiconductor device 330 of FIGS. 17 and 18.

FIG. 20 is a cross-section view conceptually showing a semiconductor device 360 formed by applying some additional steps to the semiconductor device 350 of FIG. 19.

FIG. 21 us a plan view showing a semiconductor device 360 of FIG. 20.

FIG. 22 is a cross-section view conceptually showing a semiconductor device 360 formed by applying some additional steps to the semiconductor device 350 of FIGS. 20 and 21.

FIG. 23 is a plan view showing the semiconductor device 360 of FIG. 22.

FIG. 24 is an operation flowchart showing a fabrication method of the semiconductor device 180 corresponding to the embodiment of FIGS. 1 to 13.

FIG. 25 is an operation flowchart showing a fabrication method of the semiconductor device 360 corresponding to the embodiment of FIGS. 14 to 23.

FIG. 26 is a conceptual diagram illustrating an equivalent circuit of a 2T0C (2 Transistor 0 Capacitor) structure to describe a semiconductor memory device according to an embodiment of the disclosure.

### DETAILED DESCRIPTION OF THE EMBODIMENTS

While the present disclosure is capable of various modifications and alternative forms, specific embodiments thereof are shown by way of example in the drawings and will herein be described in detail. It should be understood, however, that there is no intent to limit the present disclosure to the particular forms disclosed, but on the contrary, the present disclosure is to cover all modifications, equivalents, and alternatives falling within the spirit and scope of the present disclosure. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

In exemplary embodiments of the present disclosure, “at least one of A and B” may refer to “at least one A or B” or “at least one of one or more combinations of A and B”. In addition, “one or more of A and B” may refer to “one or more of A or B” or “one or more of one or more combinations of A and B”.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Meanwhile, even if a technology is known prior to the filing date of the present disclosure, it may be included as part of the configuration of the present disclosure when necessary, and will be described herein without obscuring the spirit of the present disclosure. However, in describing the configuration of the present disclosure, a detailed description on matters that can be clearly understood by those skilled in the art as a known technology prior to the filing date of the present disclosure may obscure the purpose of the present disclosure, so excessively detailed description on the known technology will be omitted.

However, the purpose of the disclosure is not to claim the rights to these known technologies, and the contents of the known technologies may be included as part of the disclosure without departing from the scope of the disclosure.

Hereinafter, exemplary embodiments of the disclosure will be described in more detail with reference to the accompanying drawings. To facilitate an overall understanding in the description of the disclosure, the same reference numerals will be assigned to the same components throughout the accompanying drawings, and redundant descriptions thereof will be omitted.

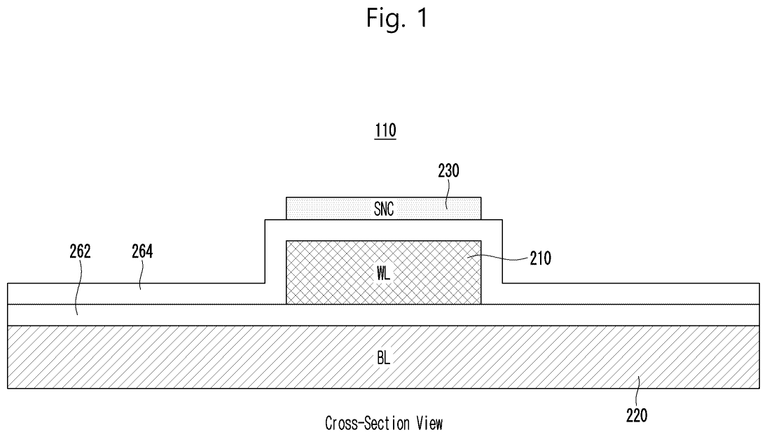

FIG. 1 is a cross-sectional view conceptually showing a semiconductor device 110 that has undergone some steps of a semiconductor fabrication process according to an embodiment of the disclosure.

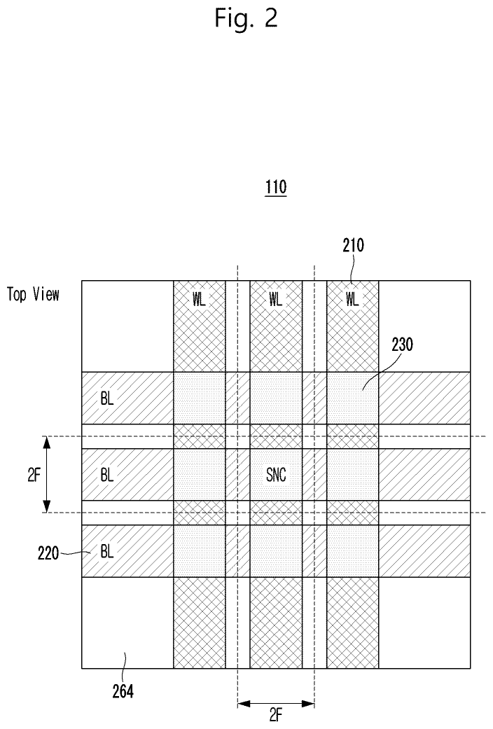

FIG. 2 is a plan view showing the semiconductor device 110 of FIG. 1.

In the process of fabricating a memory semiconductor, Feature Size (F) indicates the size of the minimum pattern (Line or Space) that can be formed by lithography.

It is known that the structure of a conventional saddle fin type cell array transistor (CAT) structure can be implemented with an area of 6F².

According to an embodiment of the disclosure, a semiconductor memory cell may have a so-called vertical cell array transistor (VCAT) structure in which a storage node contact (SNC), i.e. a capacitor, is positioned on a region where a bit line BL and a word line WL intersect perpendicularly. It is known that the VCAT structure can be implemented with an area of 4F².

Referring to FIGS. 1 and 2, the semiconductor device 110 may have a structure in which a plurality of bit lines BL 220 extending in a first direction are formed and then a first offset dielectric layer 262 is formed.

In this case, the BL 220 may be implemented using wiring including materials having low resistance such as Cu, Al, Mo, Ti, TIN, TiW, etc. In addition, the BL 220 may be implemented using combinations of one or more materials such as Cu, Al, Mo, Ti, TiN, and TiW.

The first offset dielectric layer 262 may be implemented using an insulating film having a dielectric constant of 2 to 10. For example, SiOx, AlOx, SiNx, etc. may be used as the first offset dielectric layer 262.

A plurality of word lines WL 210 extending in a second direction intersecting the first direction may be formed on the first offset dielectric layer 262, and then a second offset dielectric layer 264 may be deposited.

In this case, the WL 210 may use wiring using materials having low resistance such as Cu, Al, Mo, Ti, TiN, and TiW. In this case, the wiring of the WL 210 may be implemented using one material having the low resistance or a combination of more than two materials.

The second offset dielectric layer 264 may be implemented using an insulating film having a dielectric constant of 2 to 10. For example, SiOx, AlOx, SiNx, etc. may be used as the second offset dielectric layer 264.

A storage node contact (SNC) electrode 230 may be formed on an intersection region where the BL 220 and the WL 210 intersect. In this case, metal having low contact resistance with the semiconductor may be used as the SNC electrode 230, and the metals such as Ni, Pt, Al, Mo, Ti, TiN, TiW, Ru, and/or RuO₂ may be used.

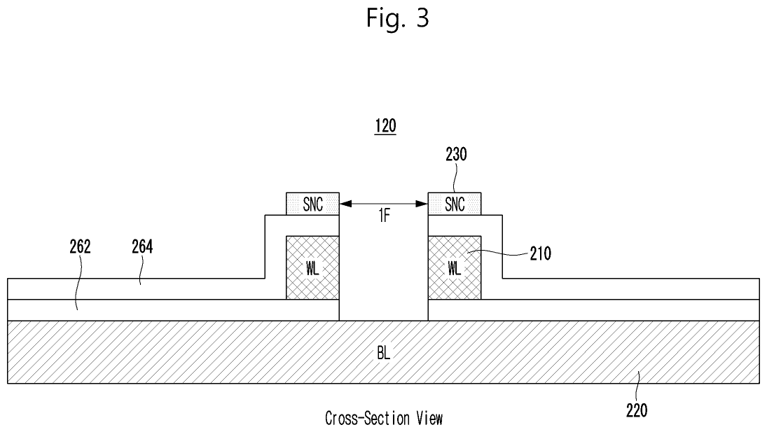

FIG. 3 is a cross-sectional diagram conceptually illustrating the semiconductor device 120 formed by applying some additional steps to the semiconductor device 110 of FIGS. 1 and 2.

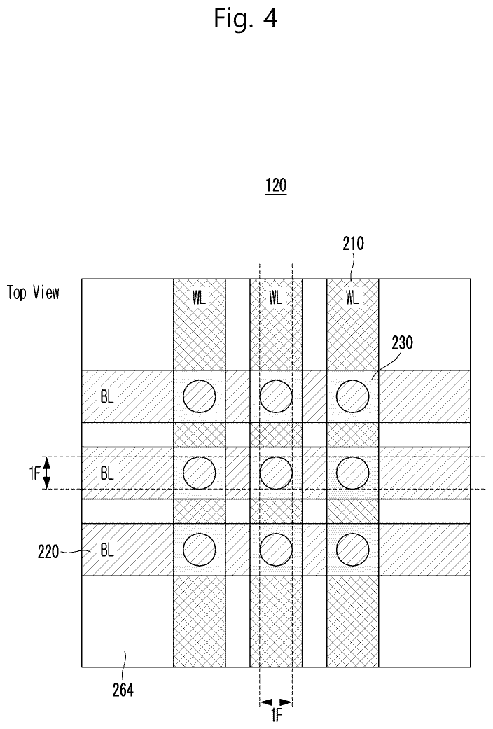

FIG. 4 is a plan view showing the semiconductor device 120 of FIG. 3.

Referring to FIGS. 3 and 4, a 1F-sized vertical channel hole penetrating the SNC electrode 230, the second offset dielectric layer 264, the WL 210, and the first offset dielectric layer 262 in the intersection region may be formed by the lithography. In this case, the hole may be etched until the BL 220 is exposed by the vertical channel hole. According to an embodiment of the disclosure, an upper portion of the BL 220 exposed by the hole may be partially etched.

FIGS. 3 and 4 illustrate an embodiment in which a cylindrical hole having a diameter of 1F is formed. However, according to various embodiments of the disclosure, the hole is formed by the lithography, and thus the horizontal cross-section of the hole may have a circular or polygonal shape. For example, the cross-section of the hole may be shaped like a polygon, such as a square, hexagon, octagon, or dodecagon. In this case, the holes shaped like polygonal columns may have a shape inscribed in a cylinder having a diameter of 1F, but are not limited thereto.

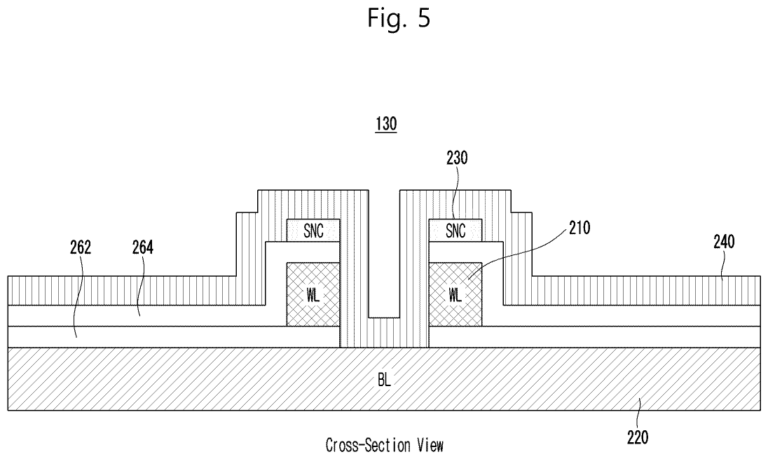

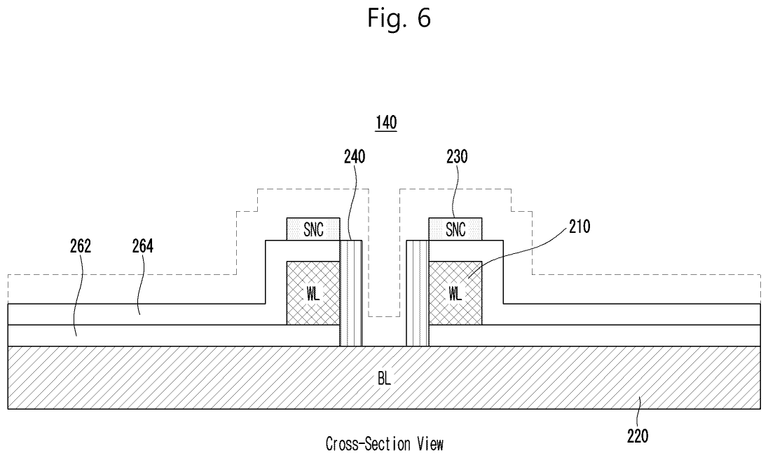

FIG. 5 is a cross-sectional view conceptually showing a semiconductor device 130 formed by applying some additional steps to the semiconductor device 120 of FIGS. 3 and 4.

Referring to FIG. 5, a gate dielectric layer 240 may be deposited as a gate insulating film after a hole is formed in the intersection region. When the gate dielectric layer 240 is deposited by a process for excellent step coverage such as an atomic layer deposition (ALD) process so that a substrate surface and a channel hole side have almost the same thickness, the gate dielectric layer 240 may be deposited without filling the hole.

The gate dielectric layer 240 may employ a dielectric film such as Al₂O₃, SiO₂, HfOx, or ZrOx. In this case, a dielectric may be formed using a combination of at least one of the foregoing compounds. As the gate dielectric layer 240, a high dielectric material having an effective dielectric constant of 10 or more may be used.

FIG. 6 is a cross-sectional view conceptually showing a semiconductor device 140 formed by applying some additional steps to the semiconductor device 130 of FIG. 5.

FIG. 7 is a plan view showing the semiconductor device 140 of FIG. 6.

Referring to FIGS. 6 and 7, after the gate dielectric layer 240 is deposited, the gate dielectric layer 240 may be etched by deep reactive ion etching, inductively coupled plasma dry etching process, or etc. having anisotropic etching characteristics until the SNC electrode 230 and the BL 220 are exposed. In this case, the etching of the gate dielectric layer 240 may be controlled to maintain the gate dielectric layer 240 on the inner side wall of the channel hole so as not to expose the WL 210.

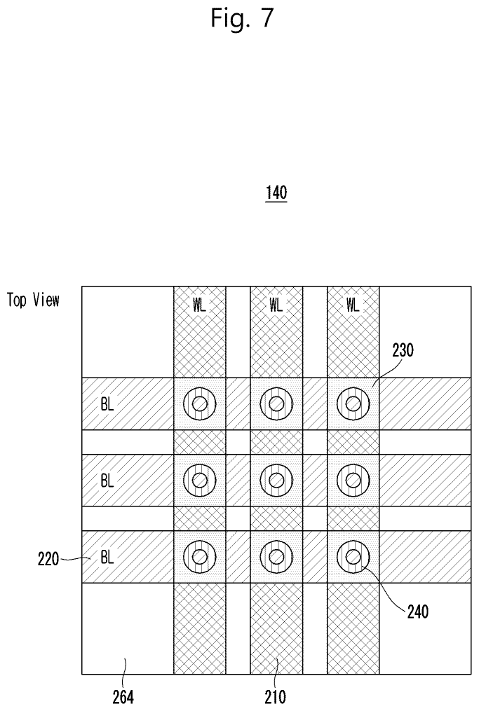

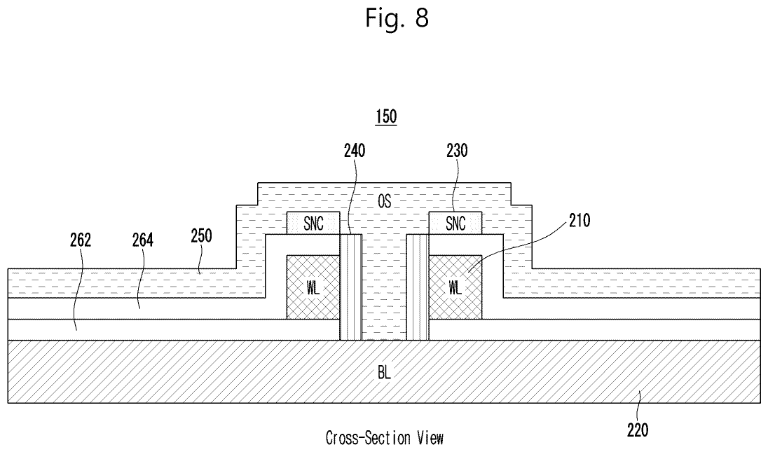

FIG. 8 is a cross-sectional view conceptually showing a semiconductor device 150 formed by applying some additional steps to the semiconductor device 140 of FIGS. 6 and 7.

Referring to FIG. 8, after the gate dielectric layer 240 is etched inside the channel hole, an oxide semiconductor 250 may be deposited using a thin film deposition process such as Sputter or ALD.

The oxide semiconductor 250 may be deposited to completely surround the inside of the channel hole. Alternatively, the oxide semiconductor 250 may be deposited to sufficiently surround the upper portion of the gate dielectric layer 240.

The oxide semiconductor 250 may include two or more elements from the group consisting of In, Ga, Zn, Sn and O. In this case, the oxide semiconductor 250 may further include at least one element such as Al, W, Hf, and/or Ta, etc. as impurities. A compound having a band gap energy of at least 1.5 eV or more may be used for the oxide semiconductor 250.

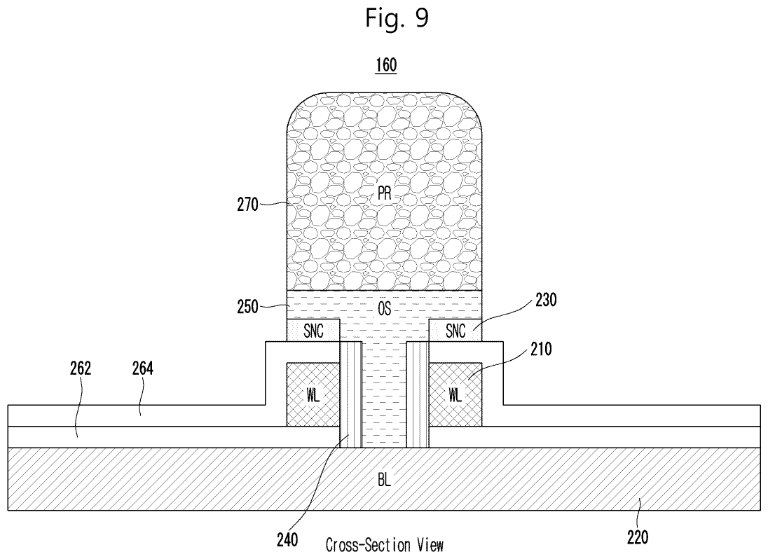

FIG. 9 is a cross-sectional view conceptually showing a semiconductor device 160 formed by applying some additional steps to the semiconductor device 150 of FIG. 8.

After the oxide semiconductor 250 is deposited, a patterning process may be performed so that only the oxide semiconductor 250 can remain on the region where the WL 210 and the BL 220 intersect for cell isolation. For the patterning process, a patterned mask layer 270 may be stacked. Photo Resist PR or Hard Mask may be used as the mask layer 270.

After the mask layer 270 is formed, all the oxide semiconductor 250 other than the oxide semiconductor 250 covered with the mask layer 270 may be removed by the etching process. To this end, the mask layer 270 may be patterned and formed only on the intersection region.

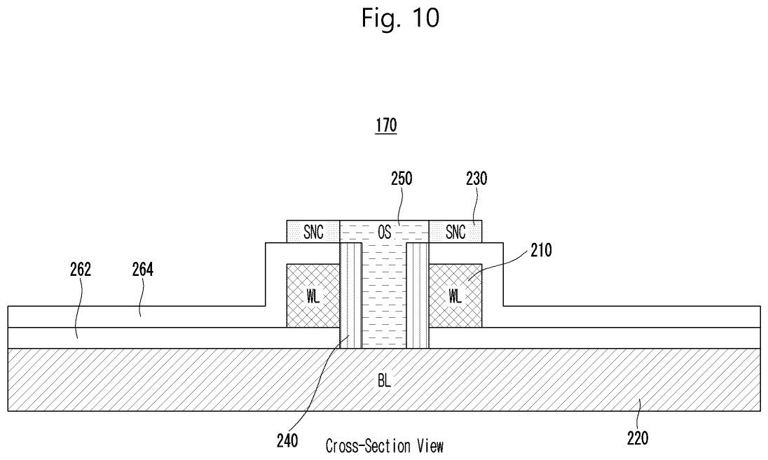

FIG. 10 is a cross-sectional view conceptually showing a semiconductor device 170 formed by applying some additional steps to the semiconductor device 160 of FIG. 9.

FIG. 11 is a plan view showing the semiconductor device 170 of FIG. 10.

Referring to FIGS. 10 and 11, a dry etching process may be performed after removing the mask layer 270 from the semiconductor device 160 of FIG. 9.

In this case, the SNC electrode 230 covered by the oxide semiconductor 250 may be exposed by the dry etching process. In other words, the dry etching process may be performed until the SNC electrode 230 covered by the oxide semiconductor 250 is exposed.

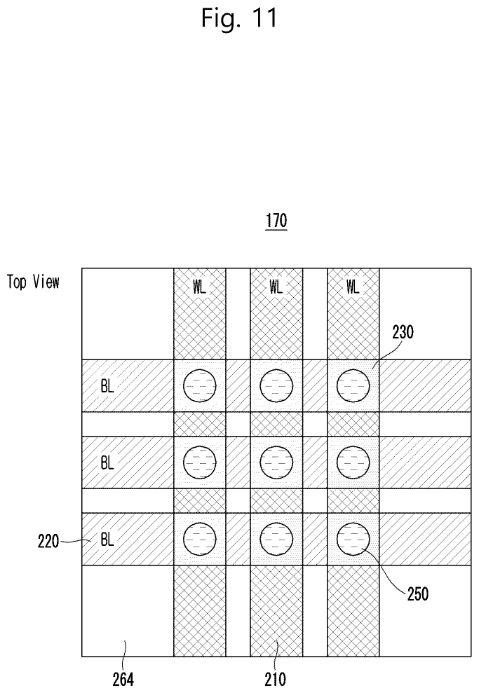

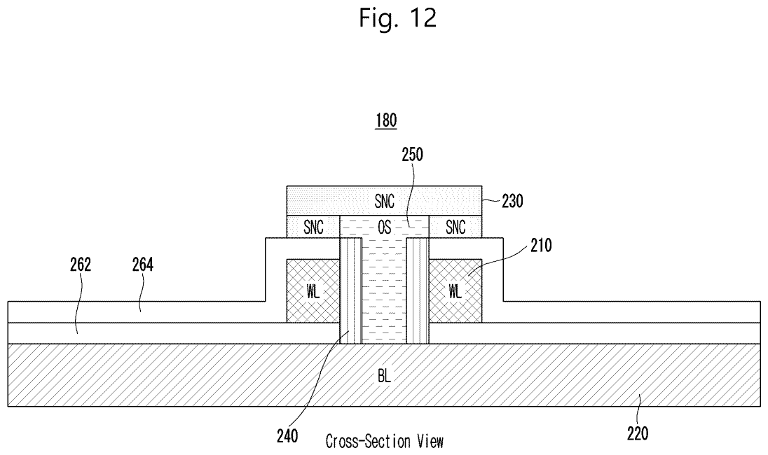

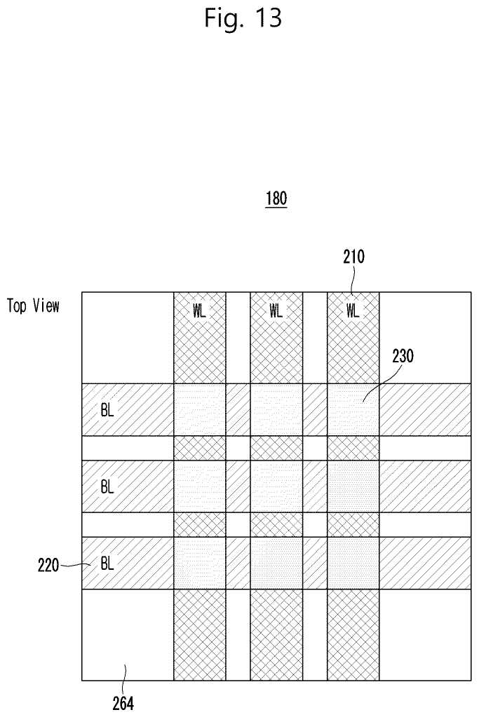

FIG. 12 is a cross-sectional view conceptually showing a semiconductor device 180 formed by applying some additional steps to the semiconductor device 170 of FIGS. 10 and 11. FIG. 13 is a plan view showing the semiconductor device 180 of FIG. 12.

Referring to FIG. 12 and FIG. 13, the SNC electrode 230 may be additionally patterned in the intersection region of the WL 210 and the BL 220. In this case, for convenience of description, a remaining portion of the SNC electrode 230 according to the embodiments of FIGS. 1 to 11 will be referred to as a first SNC electrode, and an additionally patterned portion in FIGS. 12 and 13 will be referred to as a second SNC electrode.

In FIGS. 12 and 13, the semiconductor device 180 may show a cell array transistor completed in itself. The SNC electrode 230 shown in the semiconductor device 180 of FIGS. 12 and 13 may serve as a bottom electrode of a capacitor. In an alternative embodiment of the disclosure, the semiconductor device 180 of FIG. 12 and FIG. 13 may undergo an additional patterning process or the like, for example, a process for forming an additional capacitor on the SNC electrode 230.

According to an embodiment of the disclosure, the semiconductor memory device 180 using a gate all around transistor may include: a plurality of bit lines 220 extending in the first direction; a plurality of word lines 210 positioned vertically higher than the plurality of bit lines 220 and extending in the second direction intersecting the first direction; a plurality of storage node capacitors 230 positioned vertically higher than the plurality of word lines 210 and stacked on a plurality of intersection regions where the plurality of bit lines 220 and the plurality of word lines 210 intersect, respectively; and a plurality of oxide semiconductor channel pillars 250 arranged to connect the plurality of bit lines 220 and the plurality of storage node capacitors 230 while penetrating the plurality of word lines 210 on the plurality of intersection regions.

In the semiconductor memory device 180 according to an embodiment of the disclosure, the plurality of word lines 210 may be formed as gate terminals to surround the plurality of oxide semiconductor channel pillars 250 on the plurality of intersection regions.

According to an embodiment of the disclosure, the semiconductor memory device 180 may further include a gate dielectric 240 disposed between the lateral sides of the plurality of oxide semiconductor channel pillars 250 and the plurality of word lines 210, and surrounding the plurality of oxide semiconductor channel pillars 250.

In the semiconductor memory device 180 according to an embodiment of the disclosure, the plurality of storage node capacitors 230 may be extended to cover the plurality of oxide semiconductor channel pillars 250 and the word lines 210, i.e., the gate terminals surrounding the plurality of oxide semiconductor channel pillars 250 on the plurality of intersection regions. In the semiconductor memory device 180 according to an embodiment of the disclosure, a portion of the plurality of storage node capacitors 230 may be formed to be in direct contact with a lateral surface of an upper portion of the plurality of oxide semiconductor channel pillars 250 while surrounding the lateral surface of the upper portion of the plurality of oxide semiconductor channel pillars 250.

For convenience of description, a portion of the storage node capacitors 230 of FIGS. 12 and 13, which extends to cover the upper surfaces of the plurality of oxide semiconductor channel pillars 250 and the word lines 210, i.e., the gate terminals surrounding the plurality of oxide semiconductor channel pillars 250, may be referred to as a second SNC. A portion of the storage node capacitors 230 of FIGS. 12 and 13, which is formed to be in direct contact with the lateral surface of the upper portion of the plurality of oxide semiconductor channel pillars 250 while surrounding the lateral surfaces of the upper portion of the plurality of oxide semiconductor channel pillars 250, may be referred to as a first SNC.

The first SNC may refer to a portion that is initially formed as shown in the semiconductor device 110 of FIGS. 1 and 2, and the second SNC may refer to a portion that is first deposited and shown in the semiconductor memory device 180 of FIGS. 12 and 13.

In the semiconductor memory device 180 of FIGS. 12 and 13, a lower portion of the plurality of oxide semiconductor channel pillars 250 may be in direct contact with a portion of an electrode upper portion forming the bit lines 220.

The upper portion of the plurality of oxide semiconductor channel pillars 250 may be in direct contact with the lower portion of the second SNC and the lateral surface of the first SNC. The first SNC and the second SNC may each form a portion of the storage node capacitor 230.

An additional capacitor structure for increasing the capacitance may be formed on the upper side of the second SNC. The additional capacitor structure may have a vertical pillar or the like structure, the inside of which is etched, and may be structured for increasing a surface area to increase the capacitance.

In the semiconductor memory device 180 according to an embodiment of the disclosure, a channel region of the plurality of oxide semiconductor channel pillars 250 may refer to a space surrounded with the gate dielectric layer 240 and the word lines 210. The entire outer perimeter of the side wall of the channel region may be surrounded with the gate dielectric layer 240 and the word lines 210.

In the semiconductor memory device 180 according to an embodiment of the disclosure shown in FIGS. 12 and 13, the SNC electrode 230 may include a region that vertically overlaps with the word lines 210, i.e., the gate terminals.

In the semiconductor memory device 180 according to an embodiment of the disclosure, the plurality of oxide semiconductor channel pillars 250 may have a vertical pillar structure, may be formed using a non-silicon element, and may be formed using a transition metal oxide semiconductor.

In the semiconductor memory device 180 according to an embodiment of the disclosure, the plurality of oxide semiconductor channel pillars 250 may be formed of an oxide semiconductor compound that contains two or more elements from the group consisting of In, Ga, Zn, Sn, and O and has a band gap energy of 1.5 eV or more. In this case, the oxide semiconductor compound may also include a compound having a band gap energy of 3 eV or more.

In this case, the plurality of oxide semiconductor channel pillars 250 may be formed of an oxide semiconductor compound that further contains at least one element of Al, W, Hf, and/or Ta as impurities.

In the semiconductor memory device 180 according to an embodiment of the disclosure, the gate dielectric 240 may include a dielectric film that contains at least one of Al₂O₃, SiO₂, HfOx, and/or ZrOx.

In the semiconductor memory device 180 according to an embodiment of the disclosure, the plurality of word lines 210 and the plurality of bit lines 220 may be insulated by a first offset dielectric 262.

In the semiconductor memory device 180 according to an embodiment of the disclosure, the plurality of storage node capacitors 230 and the plurality of word lines 210 may be insulated by a second offset dielectric 264.

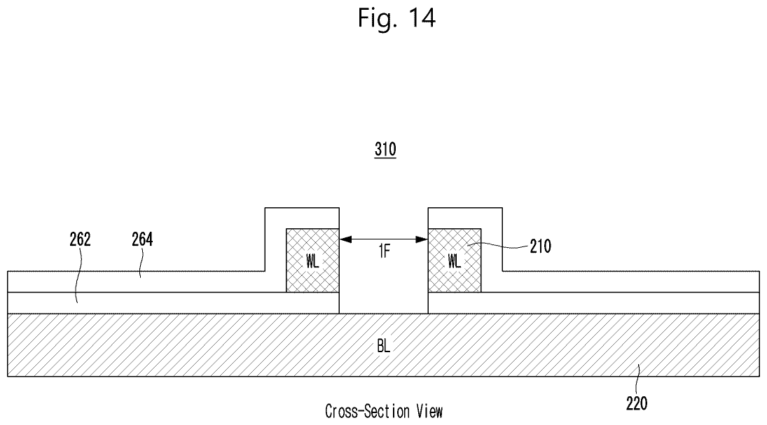

FIG. 14 is a cross-section view conceptually showing a semiconductor device 310 that has undergone some steps of a semiconductor fabrication process according to another embodiment of the disclosure.

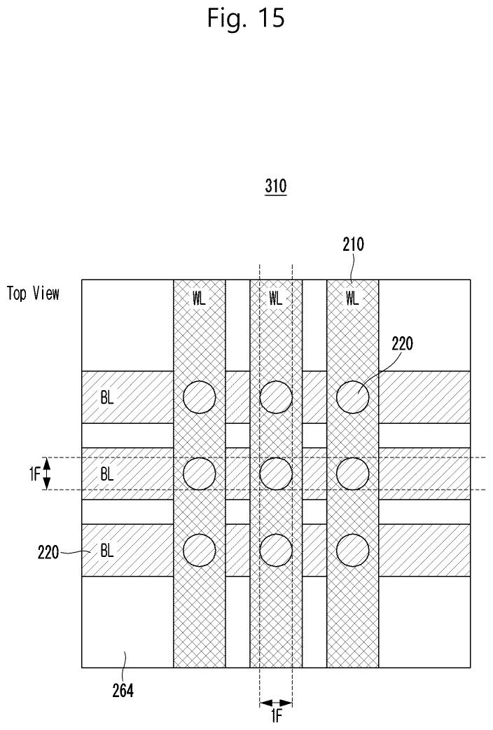

FIG. 15 is a plan view showing the semiconductor device 310 of FIG. 14.

The semiconductor device 310 of FIGS. 14 and 15 may have a structure in which a plurality of bit lines BL 220 extending in a first direction are formed and then a first offset dielectric layer 262 is formed.

In this case, the BL 220 may be implemented using wiring including materials having low resistance such as Cu, Al, Mo, Ti, TIN, TiW, etc. In addition, the BL 220 may be implemented using combinations of one or more materials such as Cu, Al, Mo, Ti, TiN, and TiW.

The first offset dielectric layer 262 may be implemented using an insulating film having a dielectric constant of 2 to 10. For example, SiOx, AlOx, SiNx, etc. may be used as the first offset dielectric layer 262.

To form the semiconductor device 310 of FIGS. 14 and 15, a plurality of word lines WL 210 extending in a second direction intersecting the first direction may be formed on the first offset dielectric layer 262, and then a second offset dielectric layer 264 may be deposited.

In this case, the WL 210 may use wiring using materials having low resistance such as Cu, Al, Mo, Ti, TiN, and TiW. In this case, the wiring of the WL 210 may be implemented using one material having the low resistance or a combination of more than two materials.

The second offset dielectric layer 264 may be implemented using an insulating film having a dielectric constant of 2 to 10. For example, SiOx, AlOx, SiNx, etc. may be used as the second offset dielectric layer 264.

Regarding descriptions of other processes, structures and materials for forming the semiconductor device 310 of FIGS. 14 and 15, repetitive descriptions to those for the semiconductor devices 110 of FIGS. 1 to 4 will be omitted.

Referring to FIGS. 14 and 15, a 1F-sized vertical channel hole penetrating the second offset dielectric layer 264, the WL 210, and the first offset dielectric layer 262 in the intersection region may be formed by the lithography. In this case, the hole may be etched until the BL 220 is exposed by the vertical channel hole. According to an embodiment of the disclosure, an upper portion of the BL 220 exposed by the hole may be partially etched.

FIGS. 14 and 15 illustrate an embodiment in which a cylindrical hole having a diameter of 1F is formed. However, according to various embodiments of the disclosure, the hole is formed by the lithography, and thus the horizontal cross-section of the hole may have a circular or polygonal shape. For example, the cross-section of the hole may be shaped like a polygon, such as a square, hexagon, octagon, or dodecagon. In this case, the holes shaped like polygonal columns may have a shape inscribed in a cylinder having a diameter of 1F, but are not limited thereto.

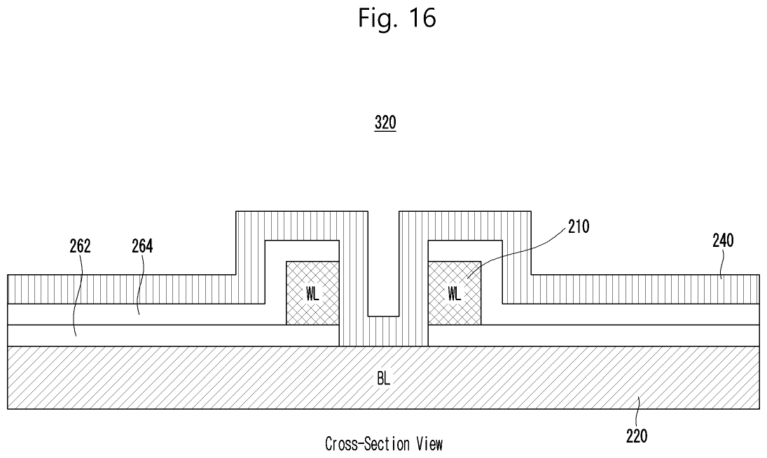

FIG. 16 is a cross-section view conceptually showing a semiconductor device 320 formed by applying some additional steps to the semiconductor device 310 of FIGS. 14 and 15.

Referring to FIG. 16, a gate dielectric layer 240 may be deposited as a gate insulating film after a hole is formed in the intersection region. When the gate dielectric layer 240 is deposited by a process for excellent step coverage such as an atomic layer deposition (ALD) process so that a substrate surface and a channel hole side have almost the same thickness, the gate dielectric layer 240 may be deposited without filling the hole.

The gate dielectric layer 240 may employ a dielectric film such as Al₂O₃, SiO₂, HfOx, or ZrOx. In this case, a dielectric may be formed using a combination of at least one of the foregoing compounds. As the gate dielectric layer 240, a high dielectric material having an effective dielectric constant of 10 or more may be used.

FIG. 17 is a cross-section view conceptually showing a semiconductor device 330 formed by applying some additional steps to the semiconductor device 320 of FIG. 16.

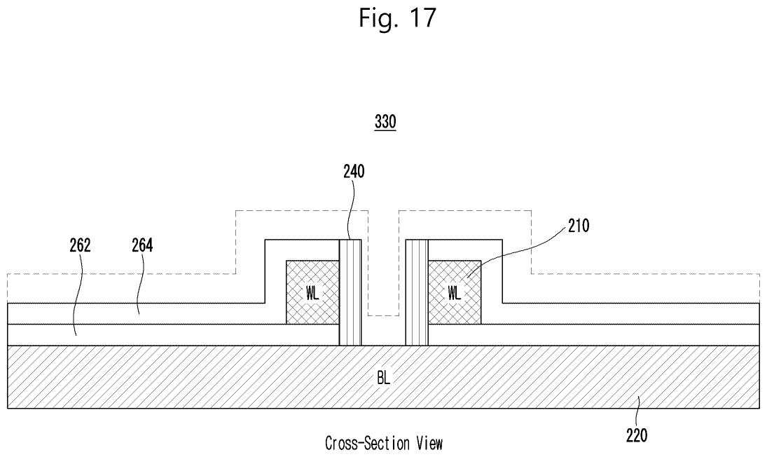

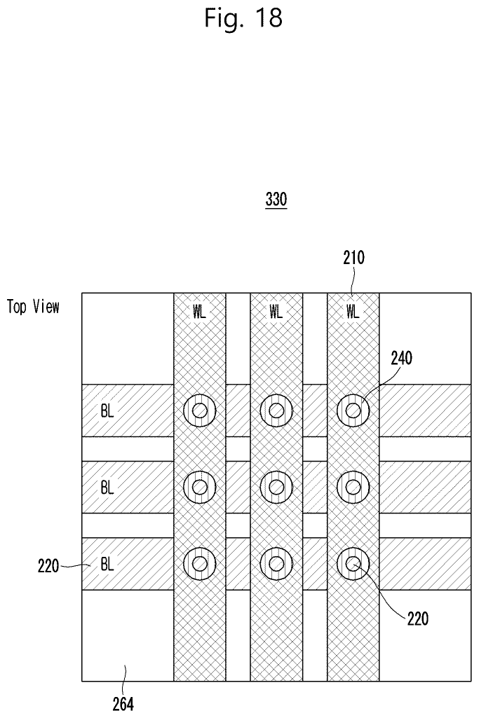

FIG. 18 is a plan view showing the semiconductor device 330 of FIG. 17.

Referring to FIGS. 17 and 18, after the gate dielectric layer 240 is deposited, the gate dielectric layer 240 may be etched by deep reactive ion etching, inductively coupled plasma dry etching process, or etc. having anisotropic etching characteristics until and the BL 220 are exposed. In this case, the etching of the gate dielectric layer 240 may be controlled to maintain the gate dielectric layer 240 on the inner side wall of the channel hole so as not to expose the WL 210.

FIG. 19 is a cross-section view conceptually showing a semiconductor device 340 formed by applying some additional steps to the semiconductor device 330 of FIGS. 17 and 18.

Referring to FIG. 19, after the gate dielectric layer 240 is etched inside the channel hole, an oxide semiconductor 250 may be deposited using a thin film deposition process such as Sputter or ALD.

The oxide semiconductor 250 may be deposited to completely surround the inside of the channel hole. Alternatively, the oxide semiconductor 250 may be deposited to sufficiently surround the upper portion of the gate dielectric layer 240.

The oxide semiconductor 250 may include two or more elements from the group consisting of In, Ga, Zn, Sn and O. In this case, the oxide semiconductor 250 may further include at least one element such as Al, W, Hf, and/or Ta, etc. as impurities. A compound having a band gap energy of at least 1.5 eV or more may be used for the oxide semiconductor 250.

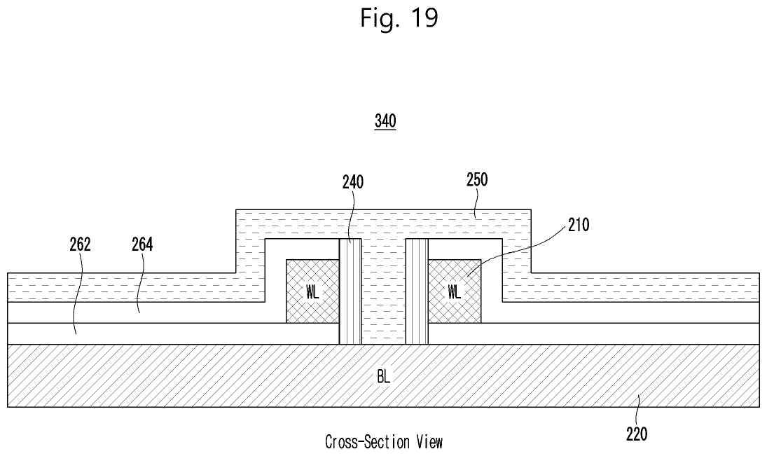

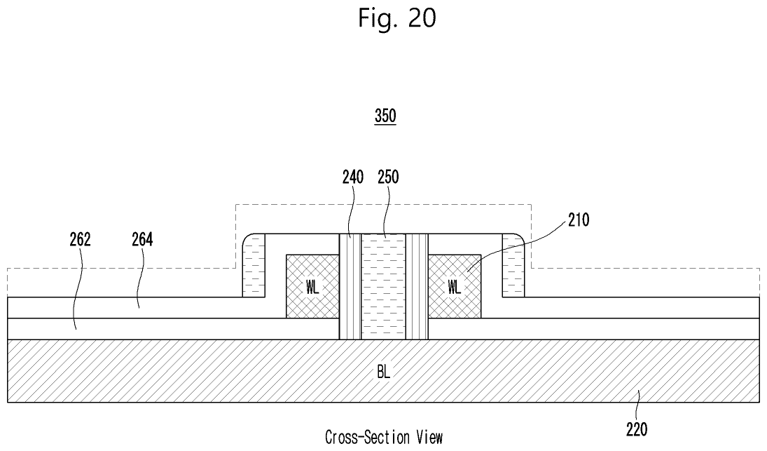

FIG. 20 is a cross-section view conceptually showing a semiconductor device 360 formed by applying some additional steps to the semiconductor device 350 of FIG. 19.

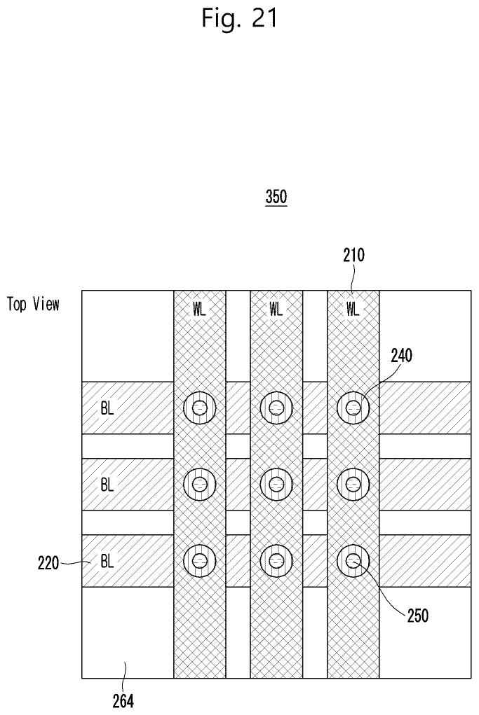

FIG. 21 us a plan view showing a semiconductor device 360 of FIG. 20.

Referring to FIGS. 20 and 21, after the oxide semiconductor 250 is deposited, a patterning process may be performed so that only the oxide semiconductor 250 can remain on the region where the WL 210 and the BL 220 intersect for cell isolation. Although omitted in FIGS. 20 and 21, a patterned mask layer 270 may be stacked for the patterning process. Photo Resist PR or Hard Mask may be used as the mask layer 270.

After the mask layer 270 is formed, all the oxide semiconductor 250 other than the oxide semiconductor 250 covered with the mask layer 270 may be removed by the etching process. To this end, the mask layer 270 may be patterned and formed only on the intersection region.

Then, the etching process of the oxide semiconductor 250 may be performed for the entire surface. The entire surface etching process may be performed until the second offset dielectric layer 264 and the gate dielectric layer 240 covered with the oxide semiconductor 250 are exposed.

In this case, the entire surface etching process should be stopped before the WL 210 corresponding to the gate terminal is exposed.

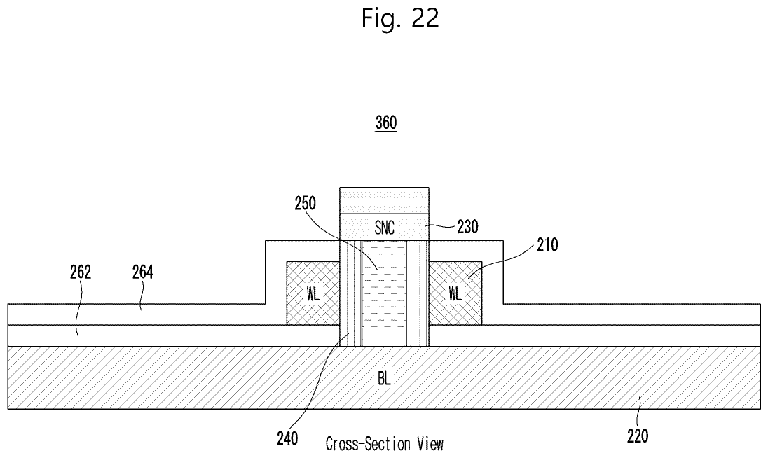

FIG. 22 is a cross-section view conceptually showing a semiconductor device 360 formed by applying some additional steps to the semiconductor device 350 of FIGS. 20 and 21.

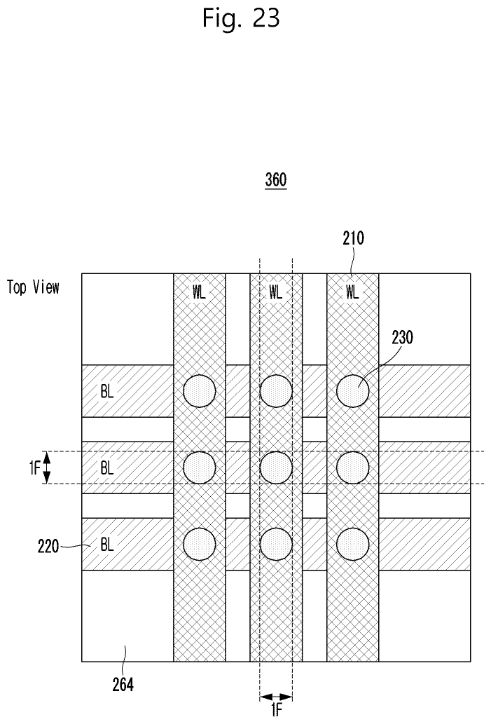

FIG. 23 is a plan view showing the semiconductor device 360 of FIG. 22.

Referring to FIG. 22 and FIG. 23, the SNC electrode 230 may be patterned in the intersection region of the WL 210 and the BL 220. In the semiconductor device 360 of FIGS. 22 and 23, the SNC electrode 230 is depicted as a cylinder having a circular cross-section having a diameter of 1F, but the cross-section of the SNC electrode 230 may have a circular or polygonal shape. In this case, the cross-section of the SNC electrode 230 may be shaped like a polygon inscribed in a circle having a diameter of 1F, but is not limited thereto.

The patterning of the SNC electrode 230 may be performed not to expose the gate dielectric layer 240 and the oxide semiconductor channel pillars 250.

Then, the cell array transistor (CAT) may be completed by removing the oxide semiconductor material other than the vertical pillar region through an additional etching process for the oxide semiconductor material.

In an alternative embodiment of the disclosure, the process of removing an oxide semiconductor remaining material other than the vertical pillar region may be performed in an etching process before patterning the SNC electrode 230.

According to an embodiment of the disclosure, the semiconductor memory device 360 using a gate all around transistor may include: a plurality of bit lines 220 extending in the first direction; a plurality of word lines 210 positioned vertically higher than the plurality of bit lines 220 and extending in the second direction intersecting the first direction; a plurality of storage node capacitors 230 positioned vertically higher than the plurality of word lines 210 and stacked on an intersection region where the plurality of bit lines 220 and the plurality of word lines 210 intersect; and a plurality of oxide semiconductor channel pillars 250 arranged to connect the plurality of bit lines 220 and the plurality of storage node capacitors 230 while penetrating the plurality of word lines 210 on the intersection region.

In the semiconductor memory device 360 according to an embodiment of the disclosure, the plurality of word lines 210 may be formed as gate terminals to surround the plurality of oxide semiconductor channel pillars 250 on the intersection region.

According to an embodiment of the disclosure, the semiconductor memory device 360 may further include a gate dielectric 240 disposed between the lateral sides of the plurality of oxide semiconductor channel pillars 250 and the plurality of word lines 210, and surrounding the plurality of oxide semiconductor channel pillars 250.

In the semiconductor memory device 360 according to an embodiment of the disclosure, the plurality of storage node capacitors 230 may be extended to cover the plurality of oxide semiconductor channel pillars 250 and the gate dielectric 240 surrounding the plurality of oxide semiconductor channel pillars 250 on the intersection region. In the semiconductor memory device 360 according to an embodiment of the disclosure, a lower portion of the plurality of storage node capacitors 230 may be formed to be in direct contact with an upper surface of the plurality of oxide semiconductor channel pillars 250.

The semiconductor memory device 360 of FIGS. 22 and 23 may be different from the semiconductor memory device 180 of FIGS. 12 and 13 in that the SNC electrode 230 is patterned on the oxide semiconductor channel pillars 250 and the gate dielectric 240 but not patterned on the word lines 210, i.e., the gate terminals.

The semiconductor memory device 360 of FIGS. 22 and 23 may be different in that the parasitic capacitance between the SNC electrode 230 and the word lines 210 is be minimized by minimizing a vertically overlapping region between the SNC electrode 230 and the word lines 210.

The semiconductor memory device 360 of FIGS. 22 and 23 may be different in that fluctuations in storage node voltage due to electric signals applied to the word lines 210 are minimized by minimizing the parasitic capacitance between the SNC electrode 230 and the word lines 210.

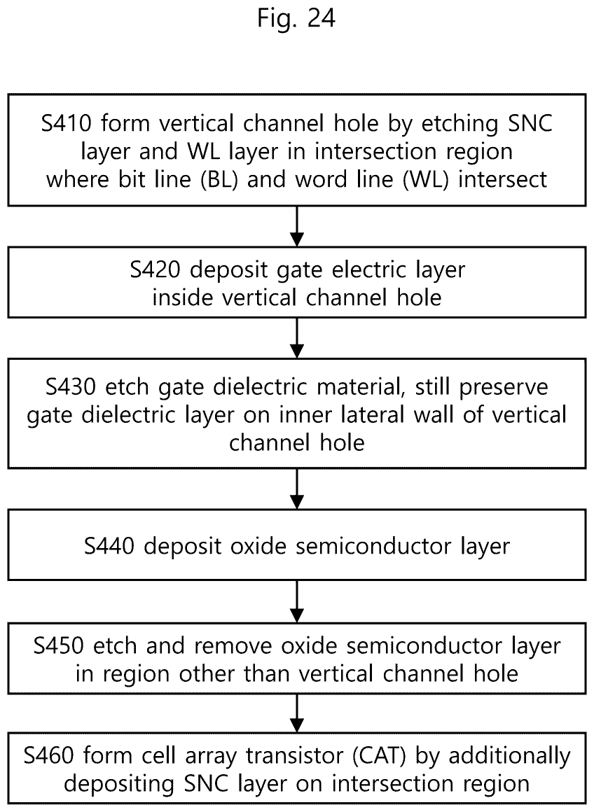

FIG. 24 is an operation flowchart showing a fabrication method of the semiconductor device 180 corresponding to the embodiment of FIGS. 1 to 13.

The method of fabricating the semiconductor device according to an embodiment of the disclosure may include steps of providing a first semiconductor device structure 110 including a plurality of first storage node capacitors stacked on an intersection region where the plurality of bit lines 220 extending in the first direction and the plurality of word lines 210 extending in the second direction intersecting the first direction intersect; forming a vertical channel hole penetrating the plurality of word lines 210 in the intersection region by etching the plurality of first storage node capacitors and the plurality of word lines 210 in the intersection region of the first semiconductor device structure 110 (S410); depositing the gate dielectric 240 on the lateral side of the vertical channel hole (S420); forming vertical oxide semiconductor channel pillars 250 by depositing an oxide semiconductor material inside the vertical channel hole and the gate dielectric 240 (S440); and forming a cell array transistor CAT by additionally depositing the second storage node capacitors on the intersection region (S460).

In the method of fabricating the semiconductor device according to an embodiment of the disclosure, the plurality of first storage node capacitors remaining after forming the vertical channel hole may be formed to be in direct contact with a lateral surface of a portion of the vertical oxide semiconductor channel pillars 250 while surrounding the lateral surface of the portion of the vertical oxide semiconductor channel pillars 250.

In this case, the second storage node capacitors may extend to cover the vertical oxide semiconductor channel pillars 250 and a portion of the plurality of word lines 210 surrounding the vertical oxide semiconductor channel pillars 250 on the intersection region.

In step S440 of forming the vertical oxide semiconductor channel pillars 250, the oxide semiconductor material including an oxide semiconductor compound that contains two or more elements from the group consisting of In, Ga, Zn, Sn, and O and has a band gap energy of 1.5 eV or more may be deposited.

In this case, the oxide semiconductor material may include an oxide semiconductor compound that further contains at least one element among Al, W, Hf, and/or Ta as impurities.

In step S420 of depositing the gate dielectric 240, the gate dielectric 240 including a dielectric film that contains at least one of Al₂O₃, SiO₂, HfOx, and ZrOx may be deposited.

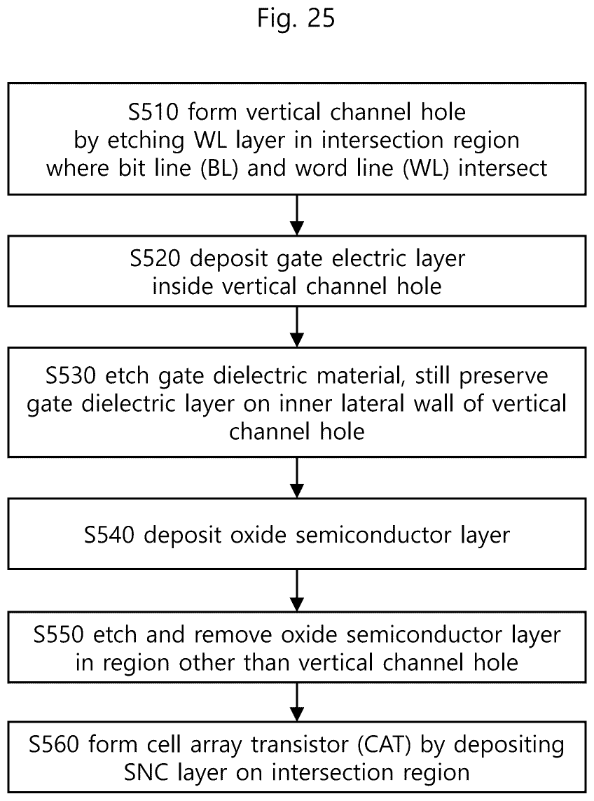

FIG. 25 is an operation flowchart showing a fabrication method of the semiconductor device 360 corresponding to the embodiment of FIGS. 14 to 23.

The method of fabricating the semiconductor device according to an embodiment of the disclosure may include steps of providing a second semiconductor device structure including the plurality of bit lines 220 extending in the first direction and the plurality of word lines 210 extending in the second direction intersecting the first direction; forming a vertical channel hole penetrating the plurality of word lines 210 in the intersection region by etching the plurality of word lines 210 in the intersection region of the second semiconductor device structure (S510); depositing the gate dielectric 240 on the lateral side of the vertical channel hole (S520); forming vertical oxide semiconductor channel pillars 250 by depositing an oxide semiconductor material inside the vertical channel hole and the gate dielectric 240 (S540); and forming a cell array transistor (CAT) by depositing the plurality of storage node capacitors 230 on the intersection region (S560).

In this case, the plurality of storage node capacitors 230 may extend to cover the vertical oxide semiconductor channel pillars 250 and the gate dielectric 240 surrounding the vertical oxide semiconductor channel pillars 250 on the intersection region.

In this case, a lower portion of the plurality of storage node capacitors 230 may be formed to be in direct contact with the upper surface of the vertical oxide semiconductor channel pillars 250.

In the embodiment of FIGS. 1 to 25, the horizontal cross-section of the vertical oxide semiconductor channel pillars 250 mainly has a circular shape, but the spirit of the disclosure is not limited to the specific embodiment.

In embodiments of the disclosure, the vertical oxide semiconductor channel pillars 250 may be patterned by a predetermined lithography method used in the etching processes S410 and S510 for forming the vertical channel hole, the process S430 and S530 for patterning the gate dielectric 240 through the deposition and the etching, etc. Accordingly, in the embodiments of the disclosure, the vertical oxide semiconductor channel pillars 250 may have a polygonal cross-section as well as a circular cross-section having a diameter of 1F. For example, cross-sections such as a square, a hexagon, and an octagon may be implemented. In this case, the polygonal cross-section of the vertical oxide semiconductor channel pillars 250 may be formed based on a polygon inscribed in the diameter of 1F, but is not limited thereto.

In the embodiments of the disclosure, the horizontal cross-sectional shape of the vertical oxide semiconductor channel pillars 250 may be determined based on the target performance and current-voltage characteristics of the GAA-FET, and may be formed based on the determined pattern.

In the semiconductor memory devices accordance to the embodiments of the disclosure shown in FIGS. 1 to 25, the plurality of oxide semiconductor channel pillars and the gate terminals surrounding the plurality of oxide semiconductor channel pillars may operate as access transistors of a DRAM having a 1T-1C (1 Transistor 1 Capacitor) structure. In this case, the plurality of storage node capacitors may operate as storage nodes of the DRAM having the 1T-1C structure.

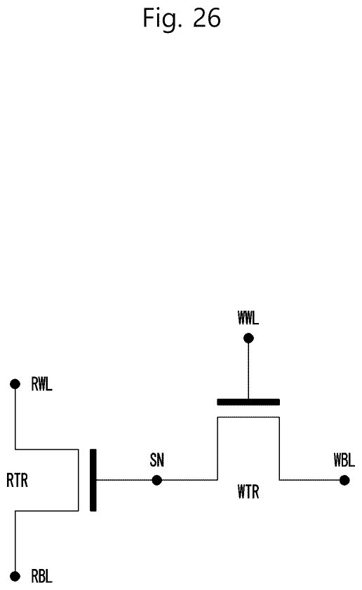

FIG. 26 is a conceptual diagram illustrating an equivalent circuit of a 2TOC (2 Transistor 0 Capacitor) structure to describe a semiconductor memory device according to an embodiment of the disclosure.

Referring to FIG. 26, the 2T-OC structure includes a write transistor WTR and a read transistor RTR.

The WTR may be connected between a write bit line WBL and a storage node SN, and a write word line WWL may control the switching of the WTR as a gate terminal of the WTR.

In the RTR, an electric current flowing to a read bit line (RBL) may be controlled based on a voltage combination between a read word line RWL and the SN while minimizing a loss of charge stored in the SN.

In an embodiment where the semiconductor memory device according to the embodiment of the disclosure shown in FIGS. 1 to 25 combines with the 2T-OC structure of FIG. 26, the plurality of oxide semiconductor channel pillars and the gate terminals surrounding the plurality of oxide semiconductor channel pillars may operate as the write transistor WTR of the DRAM having the 2T-OC (2 Transistor 0 Capacitor) structure.

In this case, the gate terminal surrounding the plurality of oxide semiconductor channel pillars may operate as the WWL of the WTR, and the plurality of oxide semiconductor channel pillars may operate as the channels of the WTR.

The plurality of storage node capacitors may operate as the storage node SN between the write transistor WTR and the read transistor RTR of the DRAM having the 2T-OC structure, and the plurality of bit lines may operate as the write bit line WBL of the DRAM having the 2T-OC structure.

According to an embodiment of the disclosure, a DRAM memory cell having an area of 4F² (where, F refers to Minimum Feature Size) may be achieved using the oxide semiconductor transistor process technology.

According to an embodiment of the disclosure, the unit area of a memory cell may be reduced to increase the integration.

According to an embodiment of the disclosure, a driving voltage may be lowered by adopting a gate all around (GAA) structure capable of efficiently controlling the short-channel effects.

According to an embodiment of the disclosure, the oxide semiconductor having a high band gap energy is used as a channel material, thereby lowering the leakage current and increasing the retention time of a cell.

According to an embodiment of the disclosure, the oxide semiconductor having a high band gap energy is used as a channel material, and thus additional processes such as additional doping are minimized and the process is simplified during the fabrication process for the memory cell array transistor (CAT) based on the GAA-FET structure, thereby reducing production costs and time.

According to an embodiment of the disclosure, the oxide semiconductor channel is used instead of the conventional Si-based channel, thereby applying a low-temperature process of less than 400 degrees to the memory semiconductor fabrication process.

According to an embodiment of the disclosure, a 3D stacking process is possible using a monolithic fabrication process without relying on 2.5D or 3D packaging technologies such as a through silicon via (TSV) or an Si interposer for the conventional 3D semiconductor packaging.

According to an embodiment of the disclosure, a memory device including a memory array transistor according to the embodiments of FIGS. 1 to 25 may be three-dimensionally stacked as multilayers based on a low-temperature process. In this case, the memory device according to an embodiment of the disclosure is three-dimensionally stacked as multilayers from a constant two-dimensional area, thereby increasing the storage capacity of a memory.

In this case, a memory device according to an embodiment of the disclosure may be stacked as multilayers by monolithic 3D stacking based on a low-temperature process. As an example of such multi-layered stacking, there is an advantage in that the structure of a high-bandwidth memory (HBM) can be implemented while minimizing dependence on packaging technology.

Further, the monolithic 3D multilayer stacking technology based on a low-temperature process makes it possible to easily implement a Processor-in-Memory (PIM) structure for stacking memory chips such as DRAM and general processor chips while minimizing the dependence on the packaging technology.

The embodiments of the disclosure illustrated in FIGS. 1 to 25 may be different from the related art in having a sequence of forming a hole by etching the inside of the WL layer 210 on each intersection between the BL 220 and the WL 210, and then forming a gate dielectric 240 and vertical oxide semiconductor channel pillars 250 inside the hole.

The operations of the method according to the exemplary embodiment of the present disclosure can be implemented as a computer readable program or code in a computer readable recording medium. The computer readable recording medium may include all kinds of recording apparatus for storing data which can be read by a computer system. Furthermore, the computer readable recording medium may store and execute programs or codes which can be distributed in computer systems connected through a network and read through computers in a distributed manner.

The computer readable recording medium may include a hardware apparatus which is specifically configured to store and execute a program command, such as a ROM, RAM or flash memory. The program command may include not only machine language codes created by a compiler, but also high-level language codes which can be executed by a computer using an interpreter.

Although some aspects of the present disclosure have been described in the context of the apparatus, the aspects may indicate the corresponding descriptions according to the method, and the blocks or apparatus may correspond to the steps of the method or the features of the steps. Similarly, the aspects described in the context of the method may be expressed as the features of the corresponding blocks or items or the corresponding apparatus. Some or all of the steps of the method may be executed by (or using) a hardware apparatus such as a microprocessor, a programmable computer or an electronic circuit. In some embodiments, one or more of the most important steps of the method may be executed by such an apparatus.

In some exemplary embodiments, a programmable logic device such as a field-programmable gate array may be used to perform some or all of functions of the methods described herein. In some exemplary embodiments, the field-programmable gate array may be operated with a microprocessor to perform one of the methods described herein. In general, the methods are preferably performed by a certain hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

What is claimed is:

1. A semiconductor memory device using gate all around transistor, comprising:
a plurality of bit lines extending in a first direction;
a plurality of word lines positioned vertically higher than the plurality of bit lines and extending in a second direction intersecting the first direction;
a plurality of storage node capacitors positioned vertically higher than the plurality of word lines and stacked on a plurality of intersection regions where the plurality of bit lines and the plurality of word lines intersect; and
a plurality of oxide semiconductor channel pillars arranged to connect the plurality of bit lines and the plurality of storage node capacitors while penetrating into the plurality of word lines on the plurality of intersection regions, wherein
the plurality of word lines surround the plurality of oxide semiconductor channel pillars as gate terminals on the plurality of intersection regions.

2. The semiconductor memory device of claim 1, further comprising a gate dielectric disposed between lateral sides of the plurality of oxide semiconductor channel pillars and the plurality of word lines, and surrounding the plurality of oxide semiconductor channel pillars.

3. The semiconductor memory device of claim 1, wherein
the plurality of storage node capacitors are extended to cover the plurality of oxide semiconductor channel pillars and gate terminals surrounding the plurality of oxide semiconductor channel pillars on the plurality of intersection regions, and
a portion of the plurality of storage node capacitors is formed to be in direct contact with a lateral surface of a portion of the plurality of oxide semiconductor channel pillars while surrounding the lateral surface of the portion of the plurality of oxide semiconductor channel pillars.

4. The semiconductor memory device of claim 1, wherein
the plurality of storage node capacitors are extended to cover the plurality of oxide semiconductor channel pillars and a gate dielectric surrounding the plurality of oxide semiconductor channel pillars on the plurality of intersection regions, and
a lower portion of the plurality of storage node capacitors is formed to be in direct contact with an upper surface of the plurality of oxide semiconductor channel pillars.

5. The semiconductor memory device of claim 1, wherein the plurality of oxide semiconductor channel pillar are formed of an oxide semiconductor compound that contains two or more elements from a group consisting of In, Ga, Zn, Sn, and O and has a band gap energy of 1.5 eV or more.

6. The semiconductor memory device of claim 5, wherein the plurality of oxide semiconductor channel pillar are formed of an oxide semiconductor compound that contains at least one element of Al, W, Hf, or Ta as impurities.

7. The semiconductor memory device of claim 2, wherein the gate dielectric comprises a dielectric film that contains at least one of Al₂O₃, SiO₂, HfOₓ, or ZrOₓ.

8. The semiconductor memory device of claim 1, wherein
the plurality of word lines and the plurality of bit lines are insulated by a first dielectric, and
the plurality of storage node capacitors and the plurality of word lines are insulated by a second dielectric.

9. The semiconductor memory device of claim 1, wherein
the plurality of oxide semiconductor channel pillars and the gate terminals surrounding the plurality of oxide semiconductor channel pillars operate as access transistors of a dynamic random-access memory (DRAM) having a 1T-1C (1 Transistor 1 Capacitor) structure, and
the plurality of storage node capacitors operate as storage nodes of the DRAM having the 1T-1C structure.

10. The semiconductor memory device of claim 1, wherein the plurality of oxide semiconductor channel pillars and the gate terminals surrounding the plurality of oxide semiconductor channel pillars operate as write transistors of the DRAM having a 2T-OC (2 Transistor 0 Capacitor) structure;
each of the plurality of storage node capacitors operates as a storage node between the write transistor and a read transistor of the DRAM having the 2T-OC structure, and each of the plurality of bit lines operates as a write bit line (WBL) of the DRAM having the 2T-OC structure.

11. A fabrication method of a semiconductor device, comprising:
providing a first semiconductor device structure comprising a plurality of first storage node capacitors stacked on a plurality of intersection regions where a plurality of bit lines extending in a first direction and a plurality of word lines extending in a second direction intersecting the first direction intersect;
forming a vertical channel hole penetrating the plurality of word lines in the plurality of intersection regions by etching the plurality of first storage node capacitors and the plurality of word lines in the plurality of intersection regions of the first semiconductor device structure;
depositing a gate dielectric on a lateral side of the vertical channel hole;
forming vertical oxide semiconductor channel pillars by depositing an oxide semiconductor material inside the vertical channel hole and the gate dielectric; and
forming a cell array transistor (CAT) by additionally depositing a second storage node capacitor on the plurality of intersection regions.

12. The fabrication method of claim 11, wherein
each of the plurality of first storage node capacitors remaining after forming the vertical channel hole is formed to be in direct contact with a lateral surface of a portion of the vertical oxide semiconductor channel pillars while surrounding the lateral surface of the portion of the vertical oxide semiconductor channel pillars, and
each of the second storage node capacitors is extended to cover the vertical oxide semiconductor channel pillars and a portion of the plurality of word lines surrounding the vertical oxide semiconductor channel pillars on the plurality of intersection regions.

13. The fabrication method of claim 11, wherein the forming the vertical oxide semiconductor channel pillars comprises depositing an oxide semiconductor material comprising an oxide semiconductor compound that contains two or more elements from a group consisting of In, Ga, Zn, Sn, and O and has a band gap energy of 1.5 eV or more.

14. The fabrication method of claim 13, wherein the oxide semiconductor material comprises an oxide semiconductor compound that contains at least one element among Al, W, Hf, or Ta as impurities.

15. The fabrication method of claim 11, wherein the depositing the gate dielectric comprises depositing the gate dielectric comprising a dielectric film that contains at least one of Al₂O₃, SiO₂, HfOₓ, or ZrOₓ.

16. A fabrication method of a semiconductor device, comprising:
providing a second semiconductor device structure comprising a plurality of bit lines extending in a first direction and a plurality of word lines extending in a second direction intersecting the first direction;
forming a vertical channel hole penetrating the plurality of word lines in a plurality of intersection regions by etching the plurality of word lines in the plurality of intersection regions of the second semiconductor device structure;
depositing a gate dielectric on a lateral side of the vertical channel hole;
forming vertical oxide semiconductor channel pillars by depositing an oxide semiconductor material inside the vertical channel hole and the gate dielectric; and
forming a cell array transistor (CAT) by depositing a plurality of storage node capacitors on the plurality of intersection regions.

17. The fabrication method of claim 16, wherein
each of the plurality of storage node capacitors extends to cover the vertical oxide semiconductor channel pillars and the gate dielectric surrounding the vertical oxide semiconductor channel pillars on the plurality of intersection regions, and
a lower portion of the plurality of storage node capacitors is formed to be in direct contact with an upper surface of the vertical oxide semiconductor channel pillars.

18. The fabrication method of claim 16, wherein the forming the vertical oxide semiconductor channel pillars comprises depositing the oxide semiconductor material that contains two or more elements from a group consisting of In, Ga, Zn, Sn, and O and has a band gap energy of 1.5 eV or more.

19. The fabrication method of claim 18, wherein the oxide semiconductor material comprises an oxide semiconductor compound that contains at least one element among Al, W, Hf, or Ta as impurities.

20. The fabrication method of claim 16, wherein the depositing the gate dielectric comprises depositing the gate dielectric comprising a dielectric film that contains at least one of Al₂O₃, SiO₂, HfOₓ, or ZrOₓ.
